(19) United States
(12) Patent Application Publication
(10) Pub. No.: US 2001/0044239 A1
(43) Pub. Date: Nov. 22, 2001

(54) High current board-to-board power connector

(76) Inventors: Carmine Gugliotti, Waterbury, CT (US); Allen J. Bernardini, Southbury, CT (US); Kenny Padro, New Haven, CT (US)

Correspondence Address: Michael H. Wallach, Esq., c/o Litton Systems, Inc., 147 Columbia Turnpike, Suite 302, Florham Park, NJ, 07932, US

(21) Appl. No.: 09/863,584

(22) Filed: May 17, 2001

Related U.S. Application Data
(60) Provisional application No. 60/205,252, filed on May 19, 2000.

(51) Int. Cl. H05K 1/00

(52) U.S. Cl. 439/668

(57) ABSTRACT

The present invention is directed to a high current electrical power connector for electrically connecting two circuit boards, such as a backplane and a daughtercard. Advantageously, the backplane connector includes a non-conductive tip and sheath to reduce the likelihood of a service technician accidentally becoming electrified.

### RELATED APPLICATION

The present application claims priority of U.S. Provisional Application Serial No. 60/205,252, filed May 19, 2000, entitled “HIGH CURRENT BOARD-TO-BOARD POWER CONNECTOR”, the disclosure of which is incorporated by reference herein in its entirety.

### FIELD OF THE INVENTION

The present invention relates generally to electrical connectors, and more particularly, to electrical power connectors. Advantageously, the present invention can be used to carry high current from one circuit board to another circuit board.

### BACKGROUND OF THE INVENTION

Electrical power connectors are often needed to carry high current between one circuit board and another circuit board. Electrical backplanes frequently have multiple daughtercards connected to the backplane which require both signal and power connectors to make electrical connections between the backplane and daughtercard. For example, a need exists in the art for a connector capable of carrying 400 amps at various voltages.

Electrical backplanes frequently are populated with multiple daughtercards. The daughtercards are connected to the backplanes using electrical connectors known in the art. From time to time it becomes desirable or necessary to change daughtercards to either change the configuration of the electrical circuit contained on the daughtercard or to replace defective daughtercards. The prior art does not adequately address a simple means for providing high current power at low voltages to the daughtercard from power supplies contained on the backplane. In addition, it would be desirable to have an electrical connector for providing power to a daughtercard from a backplane in which the power connection between the backplane and the daughtercard is effected simultaneously with inserting the daughtercard into the electrical connector which transfers electrical signals between the backplane and daughtercard.

### SUMMARY OF THE INVENTION

It is, therefore, an object of the present invention to provide an electrical power connector capable of carrying 400 amps at various voltages.

Another object of the present invention is to provide a electrical power connector having a non-conductive sheath and tip thereby reducing the likelihood of a service technician accidentally becoming electrified.

Another object of the present invention is to provide an electrical conductor using a plurality of leaf springs for carrying current between a male and female connector.

Yet another object of the present invention is to provide an electrical power connector for providing power from an electrical backplane to one or more daughtercards mounted on the backplane.

The present invention is directed to a high current electrical power connector for electrically connecting two circuit boards, such as a backplane and a daughtercard. Advantageously, the backplane connector includes a non-conductive tip and sheath to reduce the likelihood of a service technician accidentally becoming electrified.

These and other objects of the present invention are achieved by an electrical power connector, including a body including a first portion with a first plurality of undercut grooves and a second portion having a second plurality of rectangular slots. A first plurality of spring contacts are each positioned in a corresponding one of the first plurality of undercut grooves. A second plurality of pins are each positioned in a corresponding one of the second plurality of rectangular slots.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious respects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1 is a perspective view of a backplane connector according to the present invention;

FIG. 2 is a perspective view of a daughtercard connector according to the present invention;

FIG. 3 is a perspective view of the daughtercard connector of FIG. 1 with a protective sheathing covering the male portion of the backplane connector;

FIGS. 4A, 4B and 4C are side, top and right elevational views of an assembled electrical power connector according to the present invention;

FIGS. 5A and 5B are top and bottom perspective views of a spring contact according to the present invention; and

FIG. 6 is a partial cross-sectional illustration depicting the backplane connector engaged with the daughtercard connector.

### BEST MODE FOR CARRYING OUT THE INVENTION

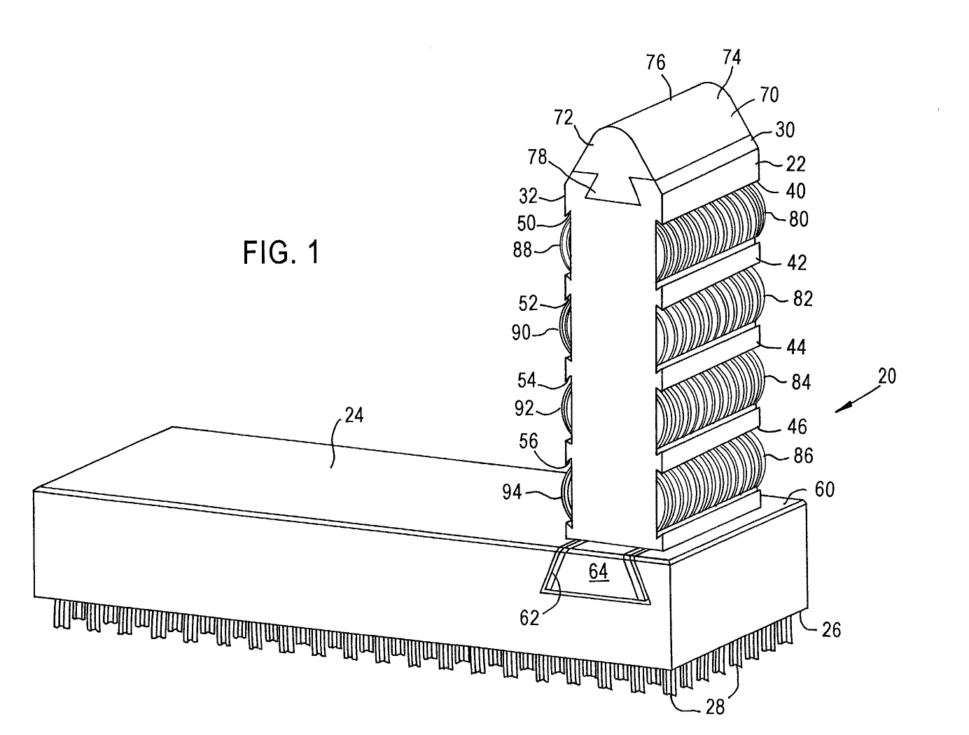

Referring first to FIG. 1, a backplane connector, generally indicated at 20, includes a backplane connecting base 24 and a male portion 22 for connecting to a daughtercard. The backplane connecting base 24 and the male portion 22 are both preferably manufactured from aluminum, brass, copper, a copper alloy or any other electrically conductive material. The male portion 22 is at right angles relative to the backplane connecting base 24 and is located at one end thereof to form an L-shaped backplane connector 20. The backplane connecting base 24 has a 1 inch width and has an 8×20 pin array for a total of 160 pins. The male portion 22 also has a one inch width. The pins 28 may be C-press® contacts which are on a lower surface 26 of the backplane connecting base 24. The C-Press pins which may be used to mount the connector to the backplane are described in U.S. Pat. No. 4,017,143, issued Apr. 12, 1977 and a power connector using such pins as described in U.S. Pat. No. 5,842,876, issued Dec. 1, 1998, both of which are hereby incorporated by reference in their entirety into this specification. A row of pins 40 are stamped from a unitary piece of metal. The pins 40 are connected to each other by a common carrier (not shown). The carrier is inserted into a groove machined into the bottom surface of the base member 26. A staking process is used to mechanically fasten the carrier and the pins 40 to the base member 26. A soldering, brazing or other mechanical fastening process can be used.

The number of contacts in the backplane connecting base 24 is a function of the amount of power to be transferred. Also, the size of the contacts and their respective mounting holes can be varied to increase or decrease the amount of power transferred between the backplane and power connector. Note also that the mounting pins 28 can either be press fit into plated holes in the respective backplane and daughtercard or soldered into the holes to effect secure mechanical and electrical connections between the backplane and connector.

It should be understood that although the connectors are depicted in FIGS. 1-4 in a horizontal position, the electrical connector 20 according to the present invention is usable in any orientation.

It should be appreciated that the electrical power connector shown and described can assist in providing physical mounting rigidity between the backplane and daughtercards and that multiple power connectors can be used for one or more daughtercards mounted on a backplane depending on the amount of power required for the daughtercard and to assist in providing mechanical rigidity between the backplane and daughtercard.

The male portion 22 has outer walls 30, 32. The outer wall 30 has a plurality of undercut grooves 40, 42, 44, 46, although any number of grooves can be used. The outer wall 32 has undercut grooves 50, 52, 54, 56. These grooves 40-46 and 50-56 extend across the entire width of the board 22. The undercut grooves 60, 62, 64 and 70, 72, 74 do not have to extend for the entire length of the walls 22, 24, respectively. For example, the grooves 60, 62, 64 and 70, 72, 74 can stop short of the end of one wall to provide a positive stop to help to retain the springs to the walls. The backplane connecting base 24 and the male portion 22 are joined together at one end 26 of base 24 on an opposite side thereof from pins 28 by a dovetail joint 60. As depicted, the female dovetail joint 62 is formed in male portion 22 and a mating male dovetail 64 is formed at one end of male portion 22.

On an opposite and distal end of the male portion 22 is an insulating member 70 having a pair of inclined surfaces 72, 74 joined by a curved surface 76 to facilitate insertion of the daughtercard connecting member into a connecting member on the daughtercard as described below. The member 70 is joined to male portion 22 using a dovetail joint 78. Insulating member 70 forms an insulating tip reducing the likelihood of a service technician accidentally becoming electrified.

The insulating tip material can be any non-conductive plastic that can operate in the temperature environment for this connector. A plurality of contact springs 80-94 are mounted in undercut grooves 40-46 and 50-56, respectively. Contact springs 80-94 extend outwardly beyond outer surfaces 30, 32 as explained in greater detail below. Each contact spring 80-94 includes a plurality of contact surfaces. Although leaf springs are shown, other types of contacts can be used, for example, a cantilevered contact having a free end to make contact with the mating daughtercard connector. It is desirable to have roughly the same number of contact surfaces on each of the contact springs 80-94 to equal the number of pins 28. Equal number of contacts are required to share in conducting the current from one connector to the other without creating hot spots if the balance is not maintained.

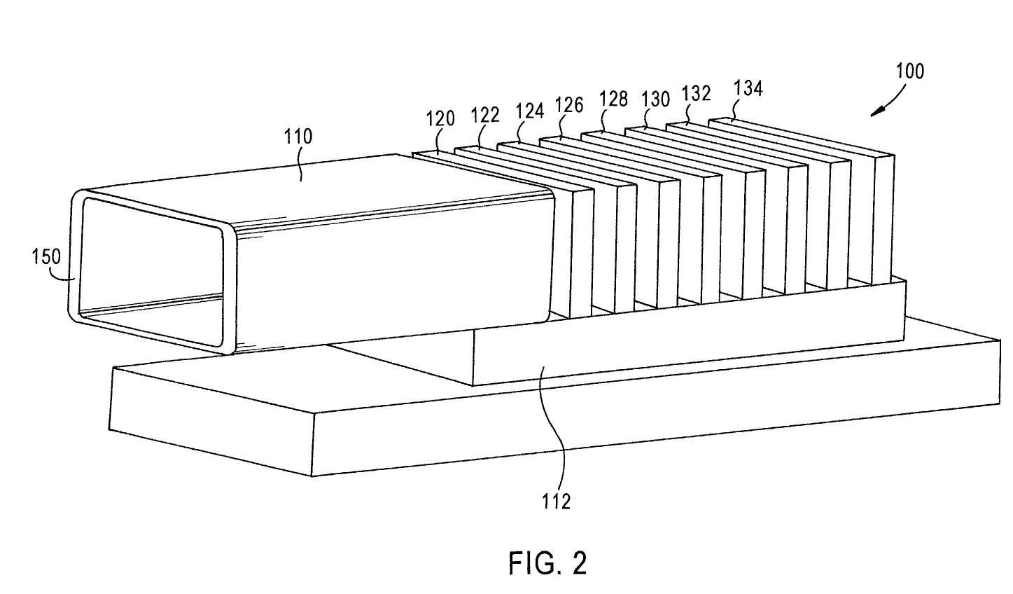

Referring now to FIG. 2, a daughtercard connector, generally indicated at 100 is depicted. The daughtercard connector 100 can have its exterior surfaces covered with an electrically insulating cover. The daughtercard connector 100 has a hollow female connector portion 110 having a length sufficient to receive the male portion 22 of the backplane connector 20. The member 110 is electrically conductive and is mounted to a contact-carrying base 112. Eight optional fins 120-134 extend transversely from the contact-carrying base 112 to help dissipate any undesired heat generated by the connector carrying 400 amps of current. The heat can be dissipated through conduction and potentially through convection. Interior walls 150 of the daughtercard connector 100 are electrically conductive sidewalls which are contacted by the springs 80-94 of the male portion.

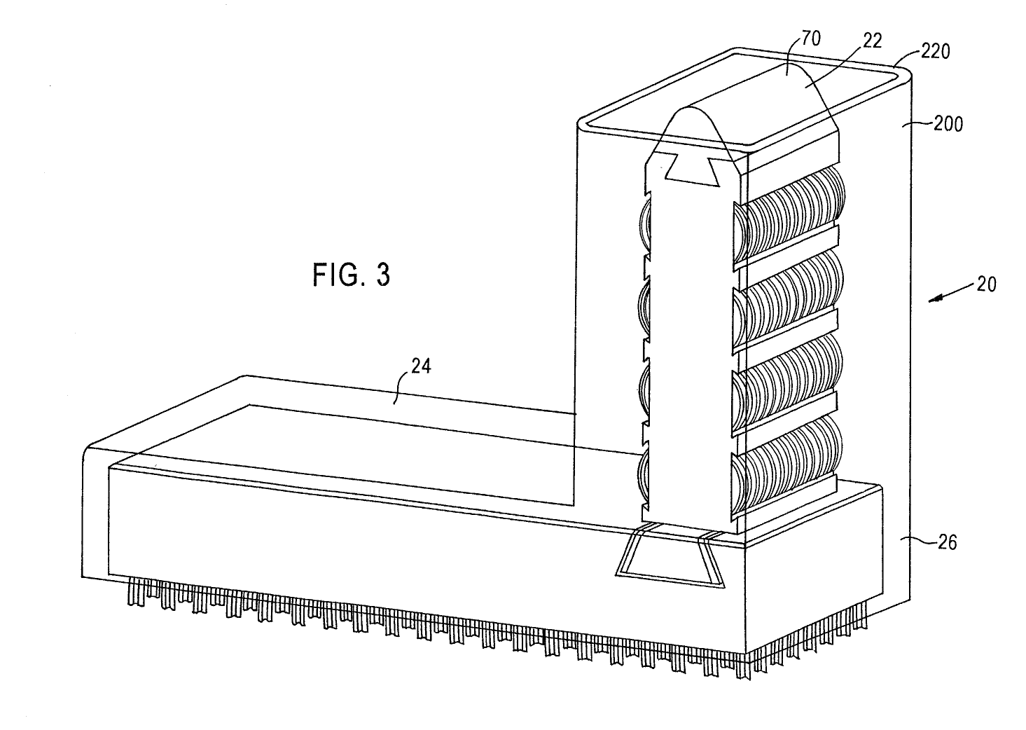

FIG. 3 is similar to FIG. 1 except a non-conductive sheath 200 surrounds the male portion 22 and is substantially co-extensive therewith. The non-conductive sheath 200 is located at one end of the connector assembly 20 and has top surfaces having inner sloping top sections 220 to facilitate intermating of the connector portions 110. The sheath 200 is held in place by a latching mechanism. The sidewalls will flex and latch on to under cut in the main body. A gap is formed between contact springs 80-94 and inner walls of the non-conductive sheath 200. The non-conductive tip 70 extends above an upper surface of the sheath 200. The sheath 200 is made from a moldable thermoplastic material capable of meeting the temperature and environmental requirements.

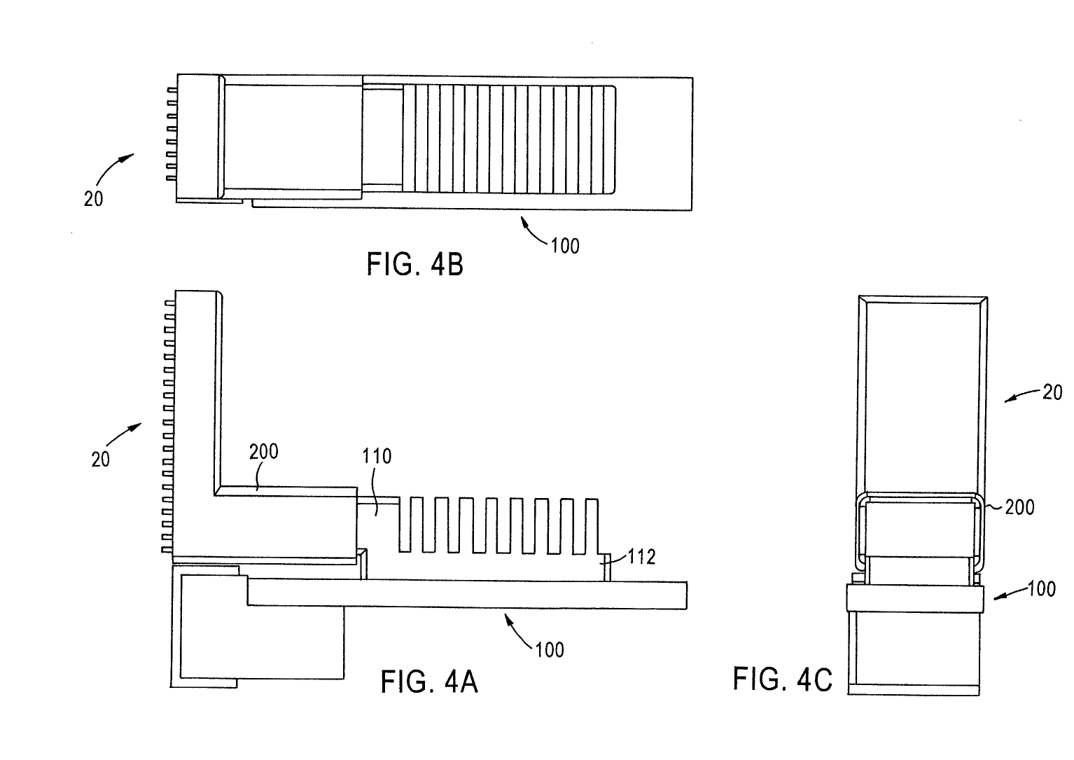

As depicted in FIGS. 4A, 4B and 4C, the daughtercard connector 100 is inserted into the backplane connector 20 to form a complete power connector assembly according to the present invention. The female connector 110 mounted on the daughtercard 100 is inserted into the sheath 200 such that the hollow member 110 comes into contact with each of the springs 80-94. Advantageously, the use of the non-conductive sheath 200 and non-conductive tip 70 prevents or minimizes the likelihood that a service technician will become electrified during mating of the connectors 20 and 100.

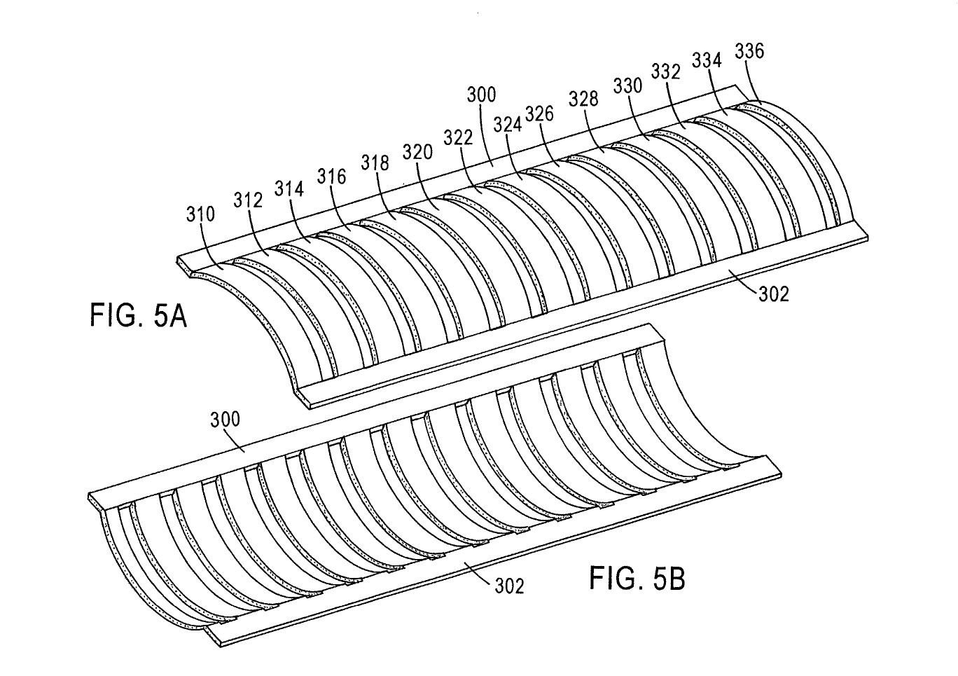

FIGS. 5A and 5B depict a contact spring 300 according to the present invention. The contact spring 300 is illustrative of the contact springs 80-94 discussed above. The contact springs are preferably formed from beryllium copper or equivalent material with the appropriate mechanical and electrical properties and can be stamped in a progressive die. The contact spring 300 has a pair of opposed longitudinal sections 300, 302. Joining the longitudinal sections are a plurality of spaced apart curved members 310-336 which extend transversely relative to the longitudinal sections 300, 302. The longitudinal sections are retained in opposite undercut portions of the undercut grooves. Each of these flexible spring contacts 310-336 forms an electrical contact point between the male connector and the female connector. One benefit of the power connector design utilizing multiple spring fingers of the type shown is to effect a tight electrical and mechanical connection between the two power connector portions evens though slight misalignment may occur between the backplane and daughtercard.

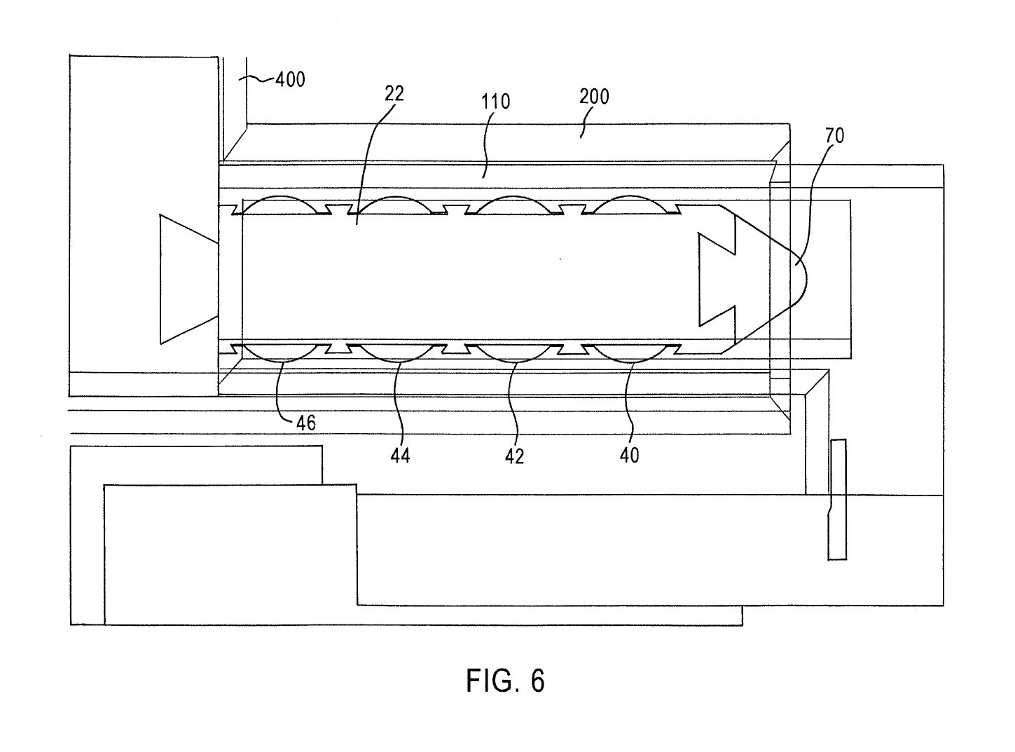

Referring now to FIG. 6, the hollow female member 110 is shown engaged with the male member 22. When the female member is engaged with the male member as depicted in FIG. 6, each of the contact springs 40-46 and 50-56 is brought into contact with the conductive inner wall of the female member 110. Each of the spring contacts forms an electrical path between the hollow member 110 and the board 22. It is not necessary to have the same number of C-Press contacts and spring members.

It should now be appreciated that an electrical power connector capable of carrying 400 amps at 1-2 volts has been described. Advantageously, the use of spring contacts simplifies the construction of the power connector. Also, the use of an electrically non-conductive sheath and an electrically non-conductive tip on the backplane connecting board minimize or reduce the likelihood of the a service technician being electrified.

Member 400 in FIG. 6 insulates the backpanel connector 20. The daughtercard connector 100 is insulated with a sheath similar to the other connector.

The power handling capability of the power connector can be modified by changing either the number of pins on the backplane and daughtercard sides of the power connector and/or the size of the pins and the plated through-holes on the backplane and daughtercard into which the pins are inserted. Also the wide and length of the base member 24 and corresponding daughtercard portion 112 can be sized to accommodate different numbers, pins and contacts and voltages and currents. The pins can either be placed in the backplane and daughtercard by friction fit into plated through-holes in the respective boards and/or can be soldered in place to effect a secure mechanical and electrical connection between circuits on the backplane and daughtercard through respective power connector portions.

It will be readily seen by one of ordinary skill in the art that the present invention fulfills all of the objects set forth above. After reading the foregoing specification, one of ordinary skill will be able to affect various changes, substitutions of equivalents and various other aspects of the invention as broadly disclosed herein. It is therefore intended that the protection granted hereon be limited only by the definition contained in the appended claims and equivalents thereof.

What is claimed is:

1. A power connector, comprising:
a body including a first portion with a first plurality of undercut grooves and a second portion having a second plurality of rectangular slots;
a first plurality of spring contacts each positioned in a corresponding one of said first plurality of undercut grooves; and
a second plurality of pins each positioned in a corresponding one of said second plurality of rectangular slots.

2. The power connector of claim 1, further comprising an electrically non-conductive member located on an end said first portion.

3. The power connector of claim 1, wherein said first portion is engageable with a daughtercard and said second portion is engageable with a backplane connector.

4. The power connector of claim 1, wherein each of said spring contacts has opposed straight sections and a plurality of curved sections connecting said opposed straight sections.

5. The power connector of claim 1, wherein said portion and said second portion are joined together with a dovetail joint.

6. The power connector of claim 1, wherein each of said spring contacts extends outwardly beyond said undercut groove.

7. The power connector of claim 1, wherein said first portion and said second portion are located at right angles relative to each other.

8. The power connector of claim 1, further comprising a hollow conductor member connected to a daughtercard to be brought into contact with each of said spring contacts.

9. The power connector of claim 1, wherein 400 amperes at 1-2 volts is carried by said power connector.

10. The power connector of claim 1, wherein said first portion is an elongated member having a first side and a second side and wherein half of said first plurality of undercut grooves are located on said first side and the other half of said first plurality of grooves are located on said second side.

11. The power connector of claim 1, wherein said first portion and said second portion are electrically conductive.

12. The power connector of claim 10, wherein said first side and said second side face outwardly.

13. The power connector of claim 4, wherein each of said curved sections forms a contact point with a hollow conductor connected to a daughtercard.

14. The power connector of claim 13, wherein there are at least 100 said contact points.

15. The power connector of claim 4, wherein said curved sections extend in a direction parallel to said first portion.

16. The power connector of claim 1, wherein said undercut grooves extend transversely relative to said first portion.

17. The power connector of claim 8, wherein each of said spring contacts bends inwardly when said hollow conductive member is brought into contact therewith.

18. The power connector of claim 1, wherein said first portion and said second portion are made of brass.

19. The power connector of claim 1, wherein each of said spring contacts is formed by beryllium copper.

20. The power connector of claim 18, wherein hollow member includes non-conductive sheathing on exterior surfaces thereof.
